(19) United States
(12) Patent Application Publication
(10) Pub. No.: US 2026/0075992 A1
(43) Pub. Date: Mar. 12, 2026

(54) LIGHT-EMITTING DIODE CHIP STRUCTURES AND RELATED METHODS

(71) Applicant: CreeLED, Inc., Durham, NC (US)

(72) Inventors: Michael Check, Holly Springs, NC (US); Steven Wuester, Wake Forest, NC (US); Daniel Carleton Driscoll, Cary, NC (US)

(21) Appl. No.: 18/883,532

(22) Filed: Sep. 12, 2024

(51) Int. Cl. H01L 33/46; H01L 33/24; H01L 33/40

(52) U.S. Cl. CPC H10H 20/841; H10H 20/821; H10H 20/835; H10H 20/032; H10H 20/034

(57) ABSTRACT

Solid-state lighting devices including light-emitting diodes (LEDs) and more particularly LED chip structures and related methods are disclosed. LED chip structures include arrangements of current spreading layers and dielectric reflective layers relative to active LED structures. Current spreading layers may be positioned to provide electron path steering toward bulk portions of active LED structures and away from associated mesa sidewalls. Dielectric reflective layers may cover current spreading layers while also extending to cover the mesa sidewalls. Dielectric reflective layers include etch stop layers followed by one or more dielectric layers. The etch stop layers allow over-etching of the dielectric layers to ensure integrity of openings for various electrical interconnects formed through the dielectric reflective layer in related methods. Arrangements of electrical interconnects are also provided that provide tailored current balancing for LED chips.

### FIELD OF THE DISCLOSURE

The present disclosure relates to solid-state lighting devices including light-emitting diodes (LEDs) and more particularly to LED chip structures and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. Photons generated by the active region are initiated in all directions.

Typically, it is desirable to operate LEDs at the highest light emission efficiency, which can be measured by the emission intensity in relation to the output power. A practical goal to enhance emission efficiency is to maximize extraction of light emitted by the active region in the direction of the desired transmission of light. Light extraction and external quantum efficiency of an LED can be limited by how well current is able to spread within an LED and by internal absorption of photons that fail to exit LED chip structures.

As advancements in modern LED technology progress, the art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs) and more particularly to LED chip structures and related methods. LED chip structures include arrangements of current spreading layers and dielectric reflective layers relative to active LED structures. Current spreading layers may be positioned to provide electron path steering toward bulk portions of active LED structures and away from associated mesa sidewalls. Dielectric reflective layers may cover current spreading layers while also extending to cover the mesa sidewalls. Dielectric reflective layers include etch stop layers followed by one or more dielectric layers. The etch stop layers allow over-etching of the dielectric layers to ensure integrity of openings for various electrical interconnects formed through the dielectric reflective layer in related methods. Arrangements of electrical interconnects are also provided that provide tailored current balancing for LED chips.

In one aspect, an LED chip comprises: an active LED structure comprising an n-type layer, a p-type layer, and an active layer between the n-type layer and the p-type layer; a dielectric reflective layer on the active LED structure, the dielectric reflective layer comprising at least one dielectric layer and an etch stop layer between the at least one dielectric layer and the active LED structure; and a current spreading layer between the etch stop layer and the active LED structure. In certain embodiments, the active LED structure defines at least one mesa bounded by a mesa sidewall, and wherein the current spreading is inset from the mesa sidewall such that a portion of the dielectric reflective layer contacts the active LED structure adjacent the current spreading layer. In certain embodiments, the at least one dielectric layer comprises an alternating layer structure formed by a plurality of first dielectric layers in an alternating arrangement with a plurality of second dielectric layers. In certain embodiments, the plurality of first dielectric layers and the plurality of second dielectric layers collectively form an aperiodic Bragg reflector. In certain embodiments, a thickest layer of the alternating layer structure is positioned closer to the active LED structure than any other layer of the alternating layer structure, and the thickest layer of the alternating layer structure is at least ten times thicker than the thinnest layer of the alternating layer structure. In certain embodiments, the etch stop layer comprises an atomic layer deposition layer. In certain embodiments, the atomic layer deposition layer comprises aluminum oxide. In certain embodiments, the etch stop layer comprises a thickness in a range from 25 nm to 200 nm. The LED chip may further comprise an adhesion layer on the dielectric reflective layer such that the at least one dielectric layer is between the adhesion layer and the etch stop layer, wherein the etch stop layer comprises a greater thickness than the adhesion layer. In certain embodiments, the etch stop layer comprises a lower porosity than the adhesion layer. The LED chip may further comprise an opening extending through the dielectric reflective layer; wherein a surface of the at least one dielectric layer at the opening forms a first angle relative to the active LED structure in a range from 15 degrees to 35 degrees; and wherein a surface of the etch stop layer at the opening forms a second angle relative to the active LED structure in a range from 70 degrees to 90 degrees. The LED chip may further comprise a substrate on the active LED structure, wherein the active LED structure is between the dielectric reflective layer and the substrate, and the substrate comprises a thickness in a range from 50 μm to 100 μm.

In another aspect, a method for forming an LED chip comprises: forming an active LED structure comprising an n-type layer, a p-type layer, and an active layer between the n-type layer and the p-type layer; forming a dielectric reflective layer on the active LED structure, the dielectric reflective layer comprising an etch stop layer and at least one dielectric layer on the etch stop layer; etching a first opening through the at least one dielectric layer to the etch stop layer; and removing portions of the etch stop layer within the first opening. The method may further comprise forming a current spreading layer on the active layer before forming the dielectric reflective layer. The method may further comprise etching a second opening through the at least one dielectric layer to the etch stop layer, and removing portions of the etch stop layer within the second opening, wherein the first opening extends to the n-type layer and the second opening extends to the current spreading layer. The method may further comprise forming an n-contact interconnect within the first opening and a reflective layer interconnect within the second opening. In certain embodiments, a surface of the at least one dielectric layer at the first opening forms a first angle relative to the active LED structure in a range from 15 degrees to 35 degrees, and a surface of the etch stop layer at the first opening forms a second angle relative to the active LED structure in a range from 70 degrees to 90 degrees.

In certain embodiments, an LED chip comprises: an active LED structure comprising an n-type layer, a p-type layer, and an active layer between the n-type layer and the p-type layer, the active LED structure forming a mesa bounded by a mesa sidewall; a dielectric reflective layer on the active LED structure; a first n-contact interconnect extending through the dielectric reflective layer from a top surface of the mesa, the first n-contact interconnect being electrically coupled with the n-type layer; a second n-contact interconnect extending through the dielectric reflective layer outside a perimeter edge of the active LED structure defined by the mesa sidewall, the second n-contact interconnect being electrically coupled with the n-type layer; a first reflective layer interconnect extending through the dielectric reflective layer from the top surface of the mesa, the first reflective layer interconnect being electrically coupled with the p-type layer; and a second reflective layer interconnect extending through the dielectric reflective layer from the top surface of the mesa, the second reflective layer interconnect being electrically coupled with the p-type layer, wherein the second reflective layer interconnect is closer to the second n-contact interconnect than the first reflective layer interconnect, and the second reflective layer interconnect is larger than the first reflective layer interconnect. In certain embodiments, the second reflective layer interconnect forms an elongated shape that is longer than a lateral width of the second n-contact interconnect. In certain embodiments, a middle portion of the second reflective layer interconnect extends parallel to the second n-contact interconnect, and end portions of the of the second reflective layer interconnect extend in an angled manner relative to the middle portion and toward the mesa sidewall. The LED chip may further comprise a third reflective layer interconnect extending through the dielectric reflective layer from the top surface of the mesa, the third reflective layer interconnect being electrically coupled with the p-type layer, wherein the third reflective layer interconnect forms a ring shape on the active LED structure and the first n-contact interconnect is aligned at a center of the ring shape. In certain embodiments, the dielectric reflective layer comprises a plurality of dielectric layers and an etch stop layer between the plurality of dielectric layers and the active LED structure. In certain embodiments, the plurality of dielectric layers comprises an aperiodic Bragg reflector. The LED chip may further comprise a current spreading layer between the etch stop layer and the active LED structure, wherein the current spreading layer is inset from the mesa sidewall such that a portion of the dielectric reflective layer contacts the active LED structure adjacent the current spreading layer. The LED chip may further comprise a substrate on the active LED structure, wherein the active LED structure is between the dielectric reflective layer and the substrate, and the substrate comprises a thickness in a range from 50 μm to 100 μm.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of an exemplary light-emitting diode (LED) chip according to principles of the present disclosure.

FIG. 2 is a cross-sectional view of a portion of the LED chip of FIG. 1 for a multiple layer embodiment of the dielectric reflective layer.

FIG. 3 is a cross-sectional view of a portion of the LED chip of FIG. 1 for another multiple layer embodiment of the dielectric reflective layer.

FIG. 4 is a cross-sectional view of a portion of the LED chip of FIG. 1 for yet another multiple layer embodiment of the dielectric reflective layer.

FIG. 5A is a cross-sectional view of a portion of the LED chip of FIG. 1 at an initial fabrication step for etching the dielectric reflective layer.

FIG. 5B is a cross-sectional view of a portion of the LED chip of FIG. 5A at a subsequent fabrication step for etching the dielectric reflective layer and the adhesion layer.

FIG. 5C is a cross-sectional view of a portion of the LED chip of FIG. 5B after continued etching of the dielectric reflective layer and the adhesion layer.

FIG. 5D is a cross-sectional view of a portion of the LED chip of FIG. 5C after removal of the photoresist of FIG. 5C.

FIG. 5E is a cross-sectional view of a portion of the LED chip of FIG. 5D after subsequent removal of portions of the etch stop layer within the opening.

FIG. 6A is a top view of an LED chip that is similar to the LED chip of FIGS. 1 to 5E and illustrates an exemplary layout of n-contact interconnects and reflective layer interconnects according to principles of the present disclosure.

FIG. 6B is a cross-sectional view of a portion of the LED chip of FIG. 6A taken along the cross-sectional line 6B-6B of FIG. 6A.

FIG. 6C is a cross-sectional view of a portion of the LED chip of FIG. 6A taken along the cross-sectional line 6C-6C of FIG. 6B.

FIG. 7A is a top view of an LED chip that is similar to the LED chip of FIGS. 6A to 6C for embodiments where the n-contact interconnects along the perimeter of the active LED structure are formed with a different shape.

FIG. 7B is a top view of an n-contact interconnect with a circular shape that may be implemented for the n-contact interconnects.

FIG. 7C is a top view of an n-contact interconnect with a triangular shape that may be implemented for the n-contact interconnects.

FIG. 7D is a top view of an n-contact interconnect with a squared shape that may be implemented for the n-contact interconnects.

FIG. 7E is a top view of an n-contact interconnect with a hexagonal shape that may be implemented for the n-contact interconnects.

FIG. 7F is a top view of an n-contact interconnect with a cross shape that may be implemented for the n-contact interconnects.

FIG. 7G is a top view of an n-contact interconnect with a trapezoid shape that may be implemented for the n-contact interconnects.

FIG. 8A is a top view of an LED package according to principles of the present disclosure.

FIG. 8B is a cross-sectional view of the LED package of FIG. 8A taken along the cross-sectional line 8B-8B of FIG. 8A.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs) and more particularly to LED chip structures and related methods. LED chip structures include arrangements of current spreading layers and dielectric reflective layers relative to active LED structures. Current spreading layers may be positioned to provide electron path steering toward bulk portions of active LED structures and away from associated mesa sidewalls. Dielectric reflective layers may cover current spreading layers while also extending to cover the mesa sidewalls. Dielectric reflective layers include etch stop layers followed by one or more dielectric layers. The etch stop layers allow over-etching of the dielectric layers to ensure integrity of openings for various electrical interconnects formed through the dielectric reflective layer in related methods. Arrangements of electrical interconnects are also provided that provide tailored current balancing for LED chips.

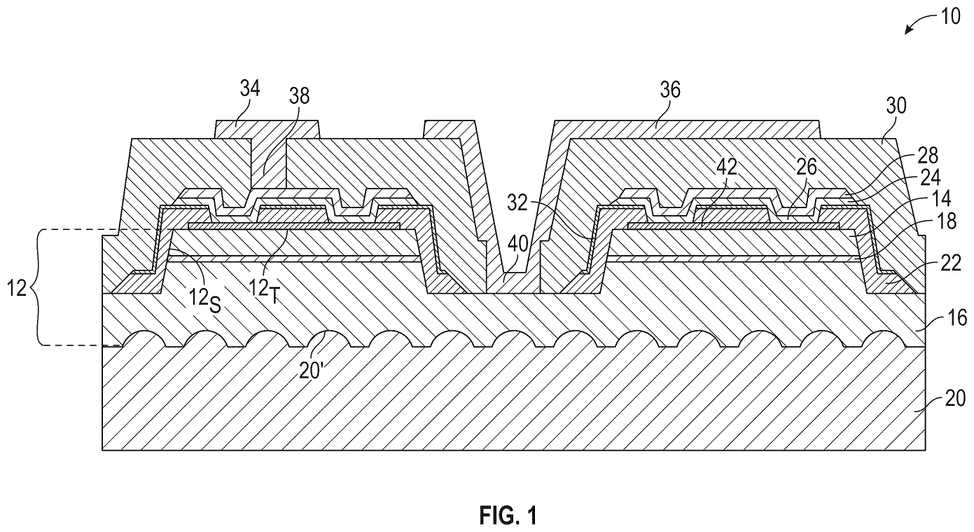

FIG. 1 is a cross-sectional view of an exemplary LED chip 10 according to principles of the present disclosure. The LED chip 10 includes an active LED structure 12 comprising a p-type layer 14, an n-type layer 16, and an active layer 18 therebetween. The active LED structure 12 may be formed on a substrate 20. In certain embodiments, one or more buffer layers and/or undoped layers may be provided between the substrate 20 and n-type layer 16 of the active LED structure 12. In certain embodiments, the n-type layer 16 is between the active layer 18 and the substrate 20. In other embodiments, the doping order may be reversed. The substrate 20 can comprise many different materials such as silicon carbide (SiC) or sapphire and can have one or more surfaces that are shaped, textured, or patterned to enhance light extraction. In certain embodiments, the substrate 20 is light transmissive (preferably transparent) and may include a patterned surface 20′ that is proximate the active LED structure 12 and includes multiple recessed and/or raised features.

In FIG. 1, a dielectric reflective layer 22 is provided on portions of the p-type layer 14. The dielectric reflective layer 22 may comprise many different materials and preferably comprises a material that presents an index of refraction step with the material of the active LED structure 12 to promote total internal reflection (TIR) of light generated from the active LED structure 12. Light that experiences TIR is redirected without experiencing absorption or loss and can thereby contribute to useful or desired LED chip emission. In certain embodiments, the dielectric reflective layer 22 comprises a material with an index of refraction lower than the index of refraction of the active LED structure 12 material. The dielectric reflective layer 22 may comprise many different materials, with some having an index of refraction less than 2.3, while others can have an index of refraction less than 2.15, less than 2.0, and less than 1.5. In certain embodiments, the dielectric reflective layer 22 comprises silicon dioxide (SiO₂) and/or silicon nitride (SiN). It is understood that many dielectric materials can be used such as SiN, SiNₓ, Si₃N₄, Si, germanium (Ge), SiO₂, SiOₓ, titanium oxide (TiOₓ) titanium dioxide (TiO₂), tantalum pentoxide (Ta₂O₅), indium tin oxide (ITO), magnesium oxide (MgOₓ), zinc oxide (ZnO), and combinations thereof. In certain embodiments, the dielectric reflective layer 22 comprises multiple alternating layers of different dielectric materials, e.g., alternating layers of SiO₂ and TiOₓ that symmetrically repeat or are asymmetrically arranged to form an asymmetric distributed Bragg reflector. Some Group III nitride materials such as gallium nitride (GaN) can have an index of refraction of approximately 2.4, SiO₂ can have an index of refraction of approximately 1.48, and SiN can have an index of refraction of approximately 1.9. Embodiments with the active LED structure 12 comprising GaN and the dielectric reflective layer 22 comprising SiO₂ may have a sufficient index of refraction step between the two to allow for efficient TIR of light. The dielectric reflective layer 22 may have different thicknesses depending on the type of materials used, with some embodiments having a thickness of at least 0.2 microns (μm). In certain multiple layer embodiments, the structure of the dielectric reflective layer 22 as described herein allows for increased thickness ranges that may be subjected to increased etching times without increased associated chip damage. In certain embodiments, the dielectric reflective layer 22 may have a thickness in the range of 0.2 μm to 1.5 μm, while in some of these embodiments the thickness may be in a range from 0.8 μm to 1.5 μm. Portions of the dielectric reflective layer 22 may extend along mesa sidewalls 12_{S} of the active LED structure 12 and along sidewall portions of the p-type layer 14, the active layer 18, and the n-type layer 16.

The LED chip 10 may further include a metal reflective layer 24 that is on the dielectric reflective layer 22 such that the dielectric reflective layer 22 is arranged between the active LED structure 12 and the metal reflective layer 24. The metal reflective layer 24 forms a structure configured to reflect any light from the active LED structure 12 that may pass through the dielectric reflective layer 22. According to aspects of the present disclosure, the metal reflective layer 24 may comprise first and second metals with varying concentrations that promote high reflectivity while also provided improved mechanical stability, improved adhesion, and reduced electromigration. Exemplary materials for the first and second metals include different ones of silver (Ag), indium (In), tin (Sn), zinc (Zn), or tin-silver-copper (SAC). As illustrated, the metal reflective layer 24 may include one or more reflective layer interconnects 26 that provide electrically conductive paths through the dielectric reflective layer 22 to the p-type layer 14. In certain embodiments, the reflective layer interconnects 26 comprise reflective layer vias. In certain embodiments, the reflective layer interconnects 26 comprise the same material as the metal reflective layer 24 and are formed at the same time as the metal reflective layer 24. In other embodiments, the reflective layer interconnects 26 may comprise a different material than the metal reflective layer 24.

The LED chip 10 may also comprise a barrier layer 28 on a side of the metal reflective layer 24 opposite the dielectric reflective layer 22 to prevent migration of metals of the metal reflective layer 24 material to other layers. Preventing this migration helps the LED chip 10 maintain efficient operation through its lifetime. The barrier layer 28 may comprise an electrically conductive material, with suitable materials including but not limited to sputtered titanium/platinum (Ti/Pt) followed by evaporated gold (Au) bulk material or sputtered titanium/nickel (Ti/Ni) followed by an evaporated Ti/Au bulk material.

A passivation layer 30 may be included on the barrier layer 28 as well as any portions of the metal reflective layer 24 that may be uncovered by the barrier layer 28. The passivation layer 30 may further be arranged on portions of the dielectric reflective layer 22 that are uncovered by the metal reflective layer 24. The passivation layer 30 protects and provides electrical insulation for the LED chip 10 and can comprise many different materials, such as a dielectric material. In certain embodiments, the passivation layer 30 is a single layer, and in other embodiments, the passivation layer 30 comprises a plurality of layers. A suitable material for the passivation layer 30 includes but is not limited to SiN, SiNx, and/or Si₃N₄. In certain embodiments, the dielectric reflective layer 22 comprises SiO₂ and the passivation layer 30 comprises SiN, SiNx, or Si₃N₄. In other embodiments, the dielectric reflective layer 22 and at least a portion of the passivation layer 30 may each comprise SiO₂. As illustrated, the dielectric reflective layer 22 may bound perimeter and/or sidewall portions 12_{S} of the active LED structure 12, including the p-type layer 14, the active layer 18, and the n-type layer 16, along a perimeter of the LED chip 10. Furthermore, the passivation layer 30 may be arranged to also bound perimeter portions of the active LED structure 12. In this manner, portions of the dielectric reflective layer 22 may be arranged between portions of the passivation layer 30 along sidewalls 12_{S} of the active LED structure 12 for enhanced passivation and protection.

Certain embodiments may also comprise an adhesion layer 32 positioned at an interface between the dielectric reflective layer 22 and the metal reflective layer 24 to promote improved adhesion therebetween. Many different materials can be used for the adhesion layer 32, such as titanium oxide (TiO, TiO₂), titanium oxynitride (TiON, TiₓO_{y}N), tantalum oxide (TaO, Ta₂O₅), tantalum oxynitride (TaON), aluminum oxide (AlO, AlₓO_{y}) or combinations thereof, with a preferred material being TiON, AlO, or AlxOy. In certain embodiments, the adhesion layer 32 comprises AlₓO_{y}, where 1≤x≤4 and 1≤y≤6. In certain embodiments, the adhesion layer 32 comprises AlₓO_{y}, where x=2 and y=3, or Al₂O₃. The adhesion layer 32 may be deposited by electron beam deposition that may provide a generally smooth, dense, and continuous layer without notable variations in surface morphology. In certain embodiments, the nature of electron beam deposition may form the adhesion layer 32 with a porosity that promotes enhanced adhesion with the metal reflective layer 24.

In FIG. 1, the LED chip 10 comprises a p-contact 34 and an n-contact 36 that are arranged on the passivation layer 30 and are configured to provide electrical connections with the active LED structure 12. The p-contact 34, which may also be referred to as an anode contact, may comprise one or more p-contact interconnects 38 that extend through the passivation layer 30 to the barrier layer 28 or the metal reflective layer 24 to provide an electrical path to the p-type layer 14. In certain embodiments, the one or more p-contact interconnects 38 comprise one or more p-contact vias. The n-contact 36, which may also be referred to as a cathode contact, is electrically coupled to the n-type layer 16 by way of one or more n-contact interconnects 40 that extend through the passivation layer 30, the barrier layer 28, the dielectric reflective layer 22, the metal reflective layer 24, the p-type layer 14, and the active layer 18. In certain embodiments, the one or more n-contact interconnects 40 may be referred to as one or more n-contact vias. Openings for the n-contact interconnects 40 may be formed in various etching steps. For illustrative purposes, FIG. 1 is shown with a single n-contact interconnect 40. In practice, the LED chip 10 may include multiple n-contact interconnects 40 spaced apart in an array pattern across the active LED structure 12.

In certain embodiments, a current spreading layer 42 may be provided between the p-type layer 14 and the dielectric reflective layer 22. The current spreading layer 42 may include a thin layer of a transparent conductive oxide such as indium tin oxide (ITO) or a thin metal layer such as Pt, although other materials may be used. As illustrated, the one or more reflective layer interconnects 26 may contact the current spreading layer 42 to provide electrically conductive pathways to the active LED structure 12. In certain embodiments, perimeter edges of the current spreading layer 42 are structured to stop short of perimeter edges of the active LED structure 12 along top surfaces 12_{T} of each mesa of the active LED structure 12. Accordingly, portions of the dielectric reflective layer 22 may contact the active LED structure 12, and in particular the top surface of the p-type layer 14 along the top surface 12_{T} of each mesa. In certain embodiments, the material of the current spreading layer 42 may be light-absorbing to wavelengths emitted by the active LED structure 12. By having the current spreading layer 42 have a smaller lateral width than the p-type layer 14, reduced absorption may be provided proximate perimeter edges and/or mesa sidewalls 12_{S} of the active LED structure 12. Additionally, this arrangement for the current spreading layer 42 provides tailored electron path steering toward the bulk of the active LED structure 12 and away from the mesa sidewalls 12_{S}, thereby reducing nonradiative recombination that may occur along the mesa sidewalls 12_{S}. In certain embodiments, having the current spreading layer 42 be inset from the mesa sidewalls 12_{S} may further protect poisoning and/or damage of the current spreading layer 42 associated with etching steps used to form the n-contact interconnects 40 and or streets along a perimeter of the LED chip 10.

In operation, a signal applied across the p-contact 34 and the n-contact 36 is conducted to the p-type layer 14 and the n-type layer 16, causing the LED chip 10 to emit light from the active layer 18. The p-contact 34 and the n-contact 36 can comprise many different materials such as Au, copper (Cu), Ni, In, aluminum (Al), Ag, Sn, Pt, or combinations thereof. In still other embodiments, the p-contact 34 and the n-contact 36 can comprise conducting oxides and transparent conducting oxides such as ITO, nickel oxide (NiO), ZnO, cadmium tin oxide, indium oxide, tin oxide, magnesium oxide, ZnGa₂O₄, ZnO₂/Sb, Ga₂O₃/Sn, AgInO₂/Sn, In₂O₃/Zn, CuAlO₂, LaCuOS, CuGaO₂, and SrCu₂O₂. The choice of material used can depend on the location of the contacts and on the desired electrical characteristics, such as transparency, junction resistivity, and sheet resistance. In certain embodiments, the LED chip 10 is arranged for flip-chip mounting and the p-contact 34 and n-contact 36 are configured to be mounted or bonded to a surface, such as a printed circuit board. While FIG. 1 is described in the context of a flip-chip structure, the principles disclosed are readily applicable to other chip structures.

As described above, the dielectric reflective layer 22 may embody a multiple-layer structure, such as an aperiodic distributed Bragg reflector. Many conventional LED chips rely primarily on a metal reflector layer made of different material such as Ag, Ag alloys, Au, and Au alloys. Optical losses may occur with each reflection off metal reflectors, and these losses can be significant, particularly for light making multiple passes and reflections in the LED chip. Optical losses are avoided in light reflected by TIR, so when more light is reflected using TIR, the emission efficiency of the LED may increase. Other conventional LEDs chips may employ conventional distributed Bragg reflectors (DBRs). A conventional DBR, such as a quarter-wave reflector, includes multiple pairs of layers with different indexes of refraction. The multiple pairs are arranged sequentially to provide multiple interfaces with index of refraction gradients. Each interface between the two layers contributes a Fresnel reflection; however, this occurs only for a particular angle of incidence range. According to aspects of the present disclosure, dielectric reflective layer 22 embodiments include multiple-layer structures with variable optical thicknesses, such as aperiodic DBRs. In this manner, each interface within the multiple-layer structure promotes TIR of light having different angles of incidence. Optical thickness may be defined as the product of the refractive index of the material and the geometric length the path of light travels. Accordingly, the optical thickness of a layer of material may be changed by increasing or decreasing the actual layer thickness. A layer with a larger optical thickness will generally promote TIR of light having shallower angles of incidence than another layer with a smaller optical thickness. Accordingly, a plurality of layers with varying optical thicknesses allow some layers to reflect more light of shallower angles of incidence while having other layers that reflect more light at greater angles of incidence, thus providing the plurality of layers with increased total reflection over all angles. Embodiments of the present disclosure provide specific optical thickness arrangements along a multiple-layer structure for the dielectric reflective layer 22 alone or in combination with additional structures, such as the arrangement of the current spreading layer 42 described above and/or etch stop layers and other structures as described below.

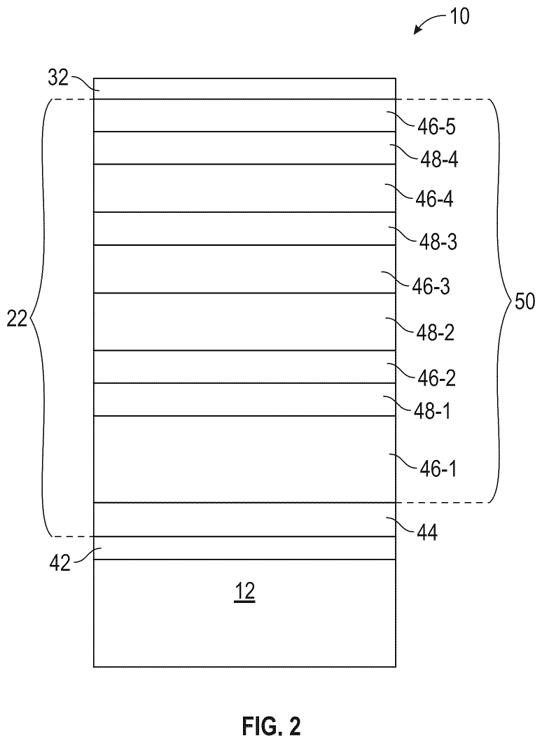

FIGS. 2 to 4 provide cross-sectional views of a portion of the LED chip 10 of FIG. 1 illustrating various multiple-layer structure embodiments of the dielectric reflective layer 22. FIGS. 2 to 4 are each provided from a same portion of the LED chip 10 where the dielectric reflective layer 22 is on the current spreading layer 42. With reference back to FIG. 1, the current spreading layer 42 may be structured with a smaller lateral width than the active LED structure 12 proximate sidewalls 12_{S} at perimeter edges of the active LED structure 12 and proximate sidewalls 12_{S} defining openings for each n-contact interconnect 40. In this regard, the view provided by FIGS. 2 to 4 may represent these areas by omitting the current spreading layer 42 such that the dielectric reflective layer 22 is directly on the active LED structure 12, such as the p-type layer 14. In each of FIGS. 2 to 4, the multiple-layer structure for the dielectric reflective layer 22 includes an etch stop layer 44 followed by an alternating series of first and second dielectric layers 46, 48 with optical thicknesses tuned for improved light extraction. The first and second dielectric layers 46, 48 collectively form an alternating layer structure 50, such as an aperiodic reflector. While the etch stop layer 44 is described in combination with variable optical thickness arrangements for the dielectric reflective layer 22, the principles described herein with respect to the etch stop layer 44 are also applicable to embodiments where the alternating layer structure 50 is a periodic Bragg reflector or embodiments where a remainder of the dielectric reflective layer 22 after the etch stop layer 44 embodies a single dielectric layer.

In FIGS. 2 to 4, the alternating layer structure 50 is formed by first dielectric layers 46 alternating with second dielectric layers 48. In certain embodiments, materials for the alternating layer structure 50 may include various combinations of SiO₂, SiOx, SiN, SiNx, Si₃N₄, Si, TiOₓ such as TiO₂, Ta₂O₅, ITO, MgOx, ZnO, or related materials. By way of example, one embodiment may include SiO₂ for the first dielectric layers 46 and TiOₓ for the second dielectric layers 48. Optical thicknesses for each layer of the alternating layer structure 50 may be varied to provide enhanced reflection for light from the active LED structure 12.

FIG. 2 is a cross-sectional view of a portion of the LED chip 10 of FIG. 1 for a multiple layer embodiment of the dielectric reflective layer 22. In the cross-sectional view of FIG. 2, the dielectric reflective layer 22 is positioned on the current spreading layer 42 which is positioned on the active LED structure 12. In certain embodiments, the adhesion layer 32 is positioned on the dielectric reflective layer 22 for promoting adhesion with the metal reflective layer 24 of FIG. 1. In FIG. 2, a first dielectric layer 46-1 is a thickest layer of the alternating layer structure 50 and may have a thickness at least two times greater than any other first dielectric layer 46-2 to 46-5. Additionally, a second dielectric layer 48-2 is a second thickest layer of the alternating layer structure 50 and is thicker than all of the first dielectric layers 46-2 to 46-5 other than the first dielectric layer 46-1. With this structure, light having a smallest angle of incidence may be subject to TIR at the initial interface formed by the first dielectric layer 46-1, and light at a next smallest angle of incidence may be subject to TIR later in the alternating layer structure 50. This may advantageously allow some light of higher angles of incidence to experience TIR without being subject to possible absorption within the second thickest layer (i.e., the second dielectric layer 48-2).

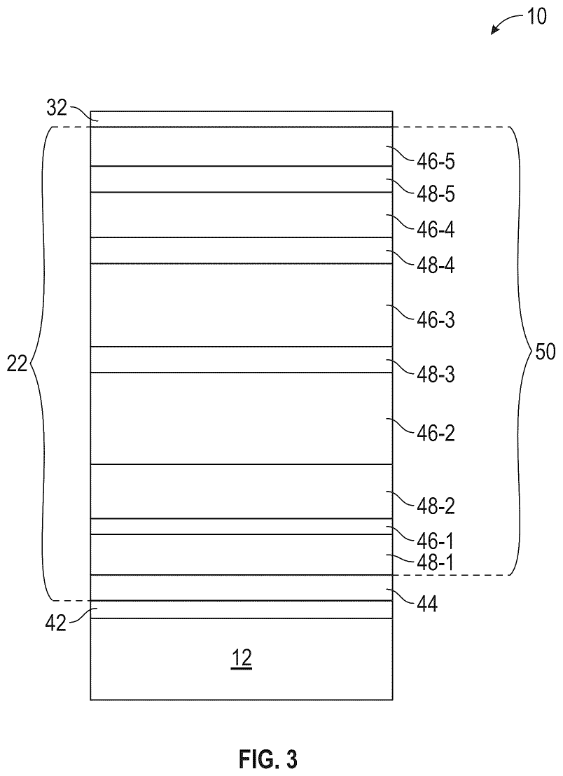

FIG. 3 is a cross-sectional view of a portion of the LED chip 10 of FIG. 1 for another multiple layer embodiment of the dielectric reflective layer 22. In FIG. 3, the second dielectric layer 48-1 is a first layer of the alternating layer structure 50 proximate the active LED structure 12. Moreover, the second dielectric layers 48-1 to 48-5 alternate with a same number of the first dielectric layers 46-1 to 46-5. In contrast to the structure of FIG. 2, the first dielectric layer 46-2 is a thickest layer of the alternating layer structure 50 and the first dielectric layer 46-3 is a second thickest layer of the alternating layer structure 50. Moreover, both first dielectric layers 46-2, 46-3 are positioned within central regions of the alternating layer structure 50. As such, multiple interfaces for light having various higher angles of incidence may be subject to TIR before reaching the two thickest layers formed by the first dielectric layers 46-2, 46-3.

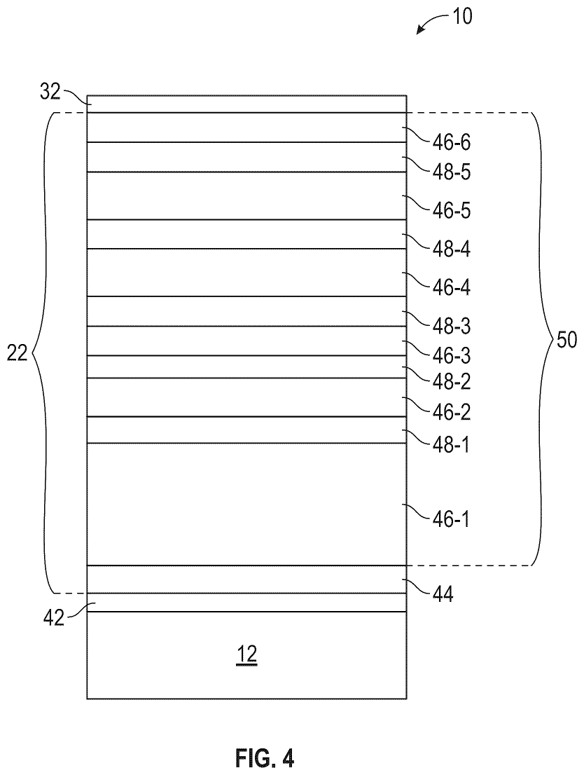

FIG. 4 is a cross-sectional view of a portion of the LED chip 10 of FIG. 1 for yet another multiple layer embodiment of the dielectric reflective layer 22. In FIG. 4, the first dielectric layer 46-1 is positioned closest to the active LED structure 12 than any other layer of the alternating layer structure 50. In a similar manner as described for FIG. 2, the first dielectric layer 46-1 is a thickest layer of the alternating layer structure 50. However, the first dielectric layer 46-1 may be at least four times thicker than any other layer of the alternating layer structure 50. In certain embodiments, the first dielectric layer 46-1 is at least ten times thicker, or at least fourteen times thicker than a thinnest layer (e.g., the second dielectric layer 48-2) of the alternating layer structure 50. Such a structure may be advantageous for embodiments where the current spreading layer 42 is inset from the sidewalls 12_{S} of the active LED structure 12 as illustrated in FIG. 1. In such embodiments, the current spreading layer 42 is structured to inject more current centrally within the active LED structure 12 and less current proximate the sidewalls 12_{S}. Accordingly, the first dielectric layer 46-1 with such greater thickness may reflect more light a lower incident angles along top surfaces (i.e., 12_{T} of FIG. 1) of each mesa of the active LED structure 12 with reduced impact of absorption of light at higher incident angles proximate the sidewalls 12_{S}.

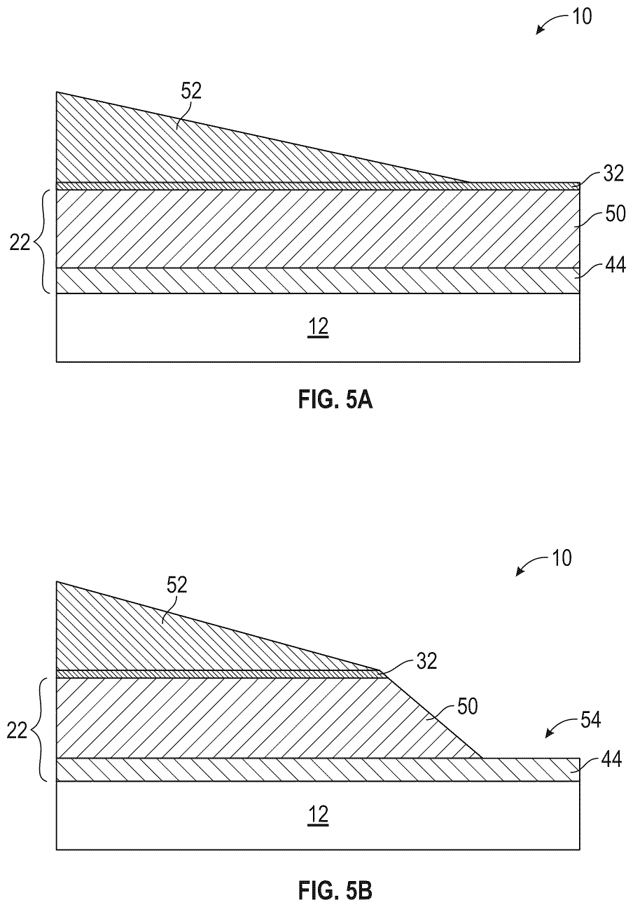

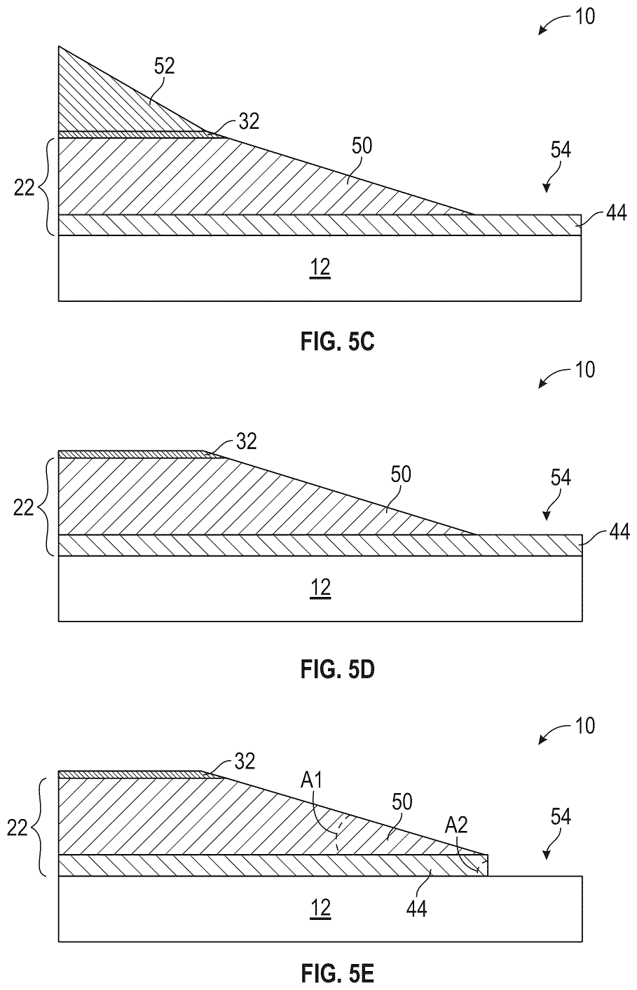

FIGS. 5A to 5E represent a series of fabrication steps for forming and etching the dielectric reflective layer 22 to provide openings therethrough for the n-contact interconnects 40 and/or the reflective layer interconnects 26 of FIG. 1. FIGS. 5A to 5E are described with respect to forming openings, which may be referred to as first openings, for the n-contact interconnects 40. However, the principles described are equally applicable to forming openings, which may be referred to as second openings, for the reflective layer interconnects 26 by adding the current spreading layer 42 between the dielectric reflective layer 22 and the active LED structure 12 as illustrated in FIG. 1. The etch stop layer 44 is provided as a first layer of the dielectric reflective layer 22. In certain embodiments, the etch stop layer 44 may be directly on the active LED structure 12 proximate the n-contact interconnects 40 of FIG. 1 or directly on the current spreading layer 42 of FIG. 1 in other areas of the active LED structure 12. In certain embodiments, the etch stop layer 44 is formed with a structure that is resistant to etchants employed to etch the alternating layer structure 50. For example, the alternating layer structure 50 may be readily etched via wet etching and/or dry etching techniques while the etch stop layer 44 is structured to be highly resistant to dry etching. Accordingly, the alternating layer structure 50 may be subjected to extended over-etching to ensure all material is removed to define the various openings so subsequent n-contact interconnects 40 and/or reflective layer interconnects 26 of FIG. 1 are not formed with reduced electrical conductivity. When dry etching is complete, exposed portions of the etch stop layer 44 may be subsequently removed by wet etching. Notably, such a sequence may further protect the current spreading layer 42 of FIG. 1 from exposure to dry etchants and avoid associated poisoning and/or damage that would create high resistive areas of the current spreading layer 42.

In certain embodiments, the etch stop layer 44 comprises an atomic layer deposition (ALD) layer with a structure that resists dry etching. By forming the etch stop layer 44 as an ALD layer, the etch stop layer 44 may structurally comprise a highly conformal layer with reduced porosity compared with other layers of the dielectric reflective layer 22 and the adhesion layer 32. Accordingly, the etch stop layer 44 may be resistant to dry etchants while also serving to provide improved passivation by effectively filling various disparities of sidewalls 12_{S} of the active LED structure 12 of FIG. 1. By way of example, the etch stop layer 44 may comprise an ALD layer of Al₂O₃ in certain embodiments with a thickness in a range from 25 nm to 200 nm, or in a range from 25 nm to 150 nm, or in a range from 35 nm to 125 nm. For comparison, the adhesion layer 32 may have a much smaller thickness, such as a range from 10 nm to 20 nm while also having increased porosity as compared with the etch stop layer 44. In certain embodiments, both the etch stop layer 44 and the adhesion layer 32 may comprise the same material, such as aluminum oxide. However, the etch stop layer 44 is formed with a different structure, such as a greater thickness and reduced porosity, to be etch resistant to dry etching. In contrast, the adhesion layer 32 may be formed by electron beam deposition to have the smaller thickness and increased porosity to promote adhesion.

FIG. 5A is a cross-sectional view of a portion of the LED chip 10 of FIG. 1 at an initial fabrication step for etching the dielectric reflective layer 22. As illustrated, the dielectric reflective layer 22 is deposited over the active LED structure 12 such that the etch stop layer 44 is between the alternating layer structure 50 and the active LED structure 12. As described above, in other areas of the LED chip 10, such as along the top surface 12_{T}, the etch stop layer 44 is between the current spreading layer 42 of FIG. 1 and the active LED structure 12. A photoresist 52 is provided on the adhesion layer 32 with a sloped surface.

FIG. 5B is a cross-sectional view of a portion of the LED chip 10 of FIG. 5A at a subsequent fabrication step for etching the dielectric reflective layer 22 and the adhesion layer 32. As described above, the etching may comprise a first etching step where dry etching is applied to form an opening 54 through the alternating layer structure 50. As illustrated, portions of the adhesion layer 32 and the alternating layer structure 50 that are uncovered by the photoresist 52 are etched to expose portions of the etch stop layer 44. During etching, lateral edges of the photoresist 52 may also be consumed.

FIG. 5C is a cross-sectional view of a portion of the LED chip 10 of FIG. 5B after continued etching of the dielectric reflective layer 22 and the adhesion layer 32. As illustrated, more of the adhesion layer 32 and the alternating layer structure 50 are removed while the etch stop layer 44 remains intact. Accordingly, the presence of the etch stop layer 44 enables extended etching conditions to ensure over etching of the adhesion layer 32 and the alternating layer structure 50 within the opening 54.

FIG. 5D is a cross-sectional view of a portion of the LED chip 10 of FIG. 5C after removal of the photoresist 52 of FIG. 5C. As illustrated, the extended etching provides a more gradual slope for etched sidewalls of the alternating layer structure 50 that extend from the opening 54.

FIG. 5E is a cross-sectional view of a portion of the LED chip 10 of FIG. 5D after subsequent removal of portions of the etch stop layer 44 within the opening 54. As described above, portions of the etch stop layer 44 may be removed by way of wet etching. The opening 54 may extend to the active LED structure 12 for forming the n-contact interconnect 40 of FIG. 1. Additionally, the same principles are applicable to portions of the LED chip 10 where the opening 54 would extend to the current spreading layer 42 of FIG. 1 for forming the reflective layer interconnect 26 of FIG. 1. As described above, the presence of the etch stop layer 44 allows over etching conditions for the alternating layer structure 50. In this manner, the resulting etched surface of the alternating layer structure 50 forms a gradual and shallow sloped surface extending away from the opening 54. In one example, the surface of the alternating layer structure 50 at the opening 54 forms an angle A1 relative to the active LED structure 12 in a range from 15° to 35°. By contrast, an etched surface of the etch stop layer 44 at the opening 54 may form an angle A2 relative to the active LED structure 12 in a range from 70° to 90°.

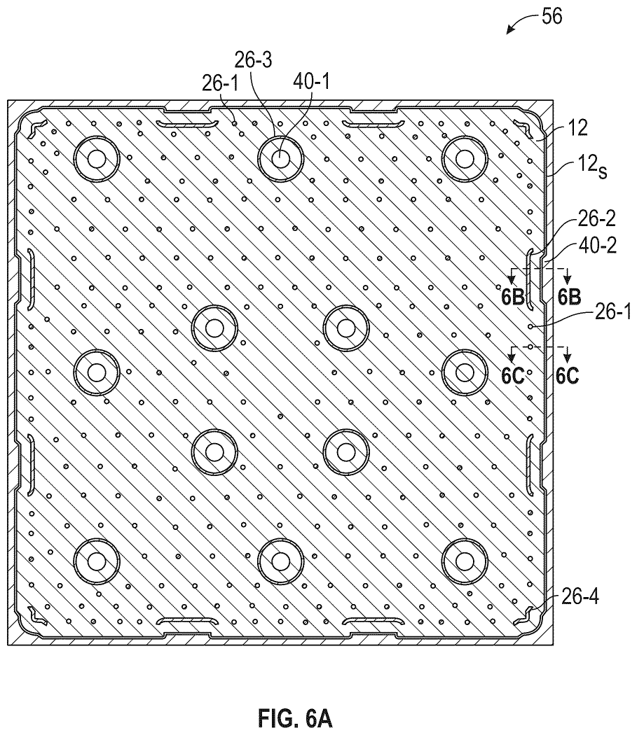

FIGS. 6A to 6C represent an exemplary layout for an LED chip 56 that is similar to the LED chip 10 of FIGS. 1 to 5E. Accordingly, the principles described above with respect to various structures of the dielectric reflective layer 22, including the alternating layer structure 50 and the etch stop layer 44, are equally applicable to the LED chip 56.

FIG. 6A is a top view of the LED chip 56 that is similar to the LED chip 10 of FIGS. 1 to 5E and illustrates an exemplary layout of n-contact interconnects 40-1 to 40-2 and reflective layer interconnects 26-1 to 26-4 according to principles of the present disclosure. In certain embodiments, multiple n-contact interconnects 40-1 may form an array across the active LED structure 12 and other n-contact interconnects 40-2 may form edge interconnects along peripheral sidewalls 12_{S} of the active LED structure 12. The n-contact interconnects 40-2 are formed along the edge of the active LED structure 12 for providing additional current injection locations along the perimeter of the active LED structure 12. In order to balance current injection across the active LED structure 12, the reflective layer interconnects 26-1 to 26-4 are formed with different shapes in different locations of the active LED structure 12. For example, certain reflective layer interconnects 26-1 form circular shapes with relatively small diameters across the active LED structure 12. Other reflective layer interconnects 26-2, 26-3 that are near one of the n-contact interconnects 40-1, 40-2 are formed with larger shapes. Current injection may be highest at or near the n-contact interconnects 40-1, 40-2. By having a larger area of reflective layer interconnects 26-2, 26-3 proximate n-contact interconnects 40-1, 40-2, current injection may be effectively balanced across the LED chip 10, thereby providing increased brightness and reduced forward voltage with increased uniformity.

By way of example, the reflective layer interconnects 26-2 are closest to the n-contact interconnects 40-2 at the perimeter of the active LED structure 12. These reflective layer interconnects 26-2 form elongated shapes that correspond to a shape of the n-contact interconnect 40-2. For example, a middle portion of each reflective layer interconnect 26-2 extends in a parallel manner to a portion of the n-contact interconnect 40-2 that laterally protrude into sidewalls 12_{S} of the active LED structure 12. End portions of each reflective layer interconnect 26-2 angle back toward the sidewalls 12_{S} on either side of each reflective layer interconnect 26-2. Accordingly, each reflective layer interconnect 26-2 is longer than a lateral width of each corresponding n-contact interconnect 40-2.

In another example, the reflective layer interconnects 26-3 are positioned closest to the n-contact interconnects 40-1 across the active LED structure 12. These reflective layer interconnects 26-3 are elongated to form ring shapes on the active LED structure with the corresponding n-contact interconnect 40-1 aligned at a center of the ring shape. In yet another example, reflective layer interconnects 26-4 are positioned proximate corners of the active LED structure 12 with elongated shapes that follow contours of the corners.

FIG. 6B is a cross-sectional view of a portion of the LED chip 56 of FIG. 6A taken along the cross-sectional line 6B-6B of FIG. 6A. This portion of the LED chip 56 illustrates the structure of the n-contact interconnect 40-2 formed outside edges of the active LED structure 12. As described above, such n-contact interconnects 40-2 provide edge current injection locations for the active LED structure 12. As further illustrated in FIG. 6B, portions of the etch stop layer 44 effectively enclose the current spreading layer 42 except in areas where the reflective layer interconnect 26-2 is formed. The etch stop layer 44 extends to cover and passivate the mesa sidewalls 12_{S}, and the etch stop layer 44 extends to cover portions of the n-type layer 16 outside the mesa.

FIG. 6C is a cross-sectional view of a portion of the LED chip 56 of FIG. 6A taken along the cross-sectional line 6C-6C of FIG. 6A. This portion of the LED chip 56 illustrates the portions of the chip perimeter that are between n-contact interconnects 40-2. In these areas, the passivation layer 30 is formed to extend past the dielectric reflective layer 22 and cover portions of the n-type layer 16 outside the mesa. Accordingly, the n-contact interconnects 40-2 of FIG. 6A form current injection locations while remaining portions of the perimeter edge of the LED chip 56 are passivated.

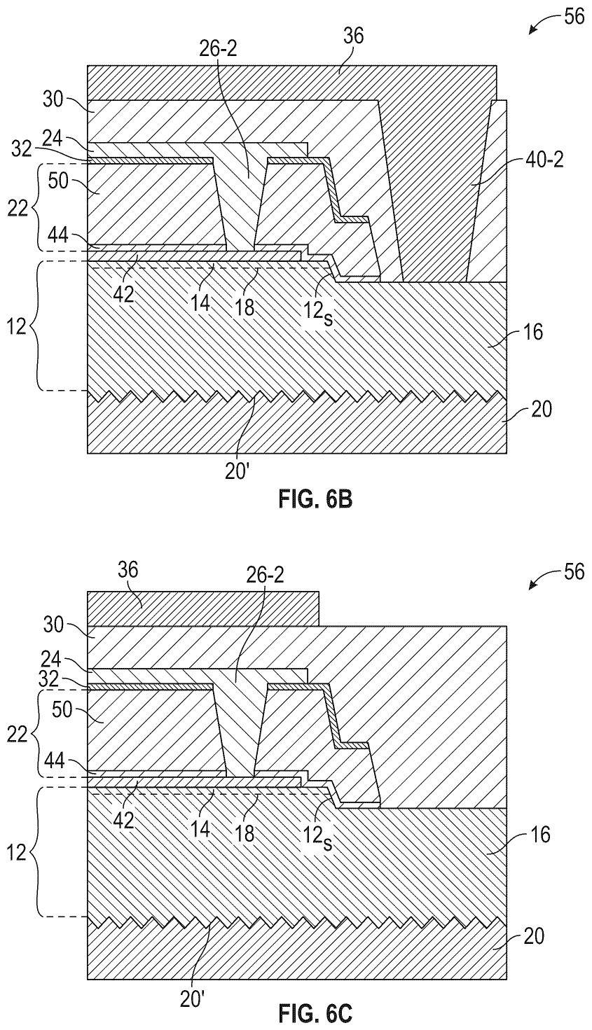

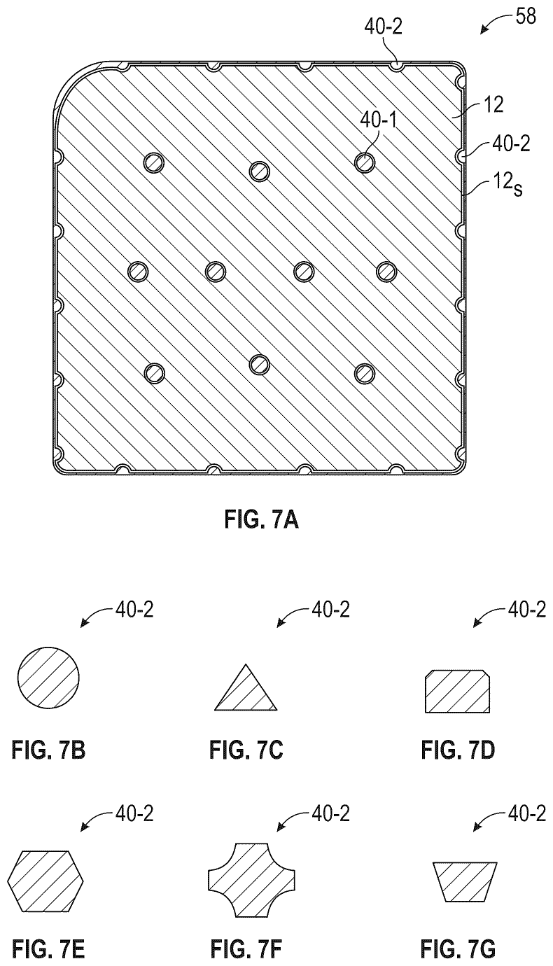

FIG. 7A is a top view of the LED chip 58 that is similar to the LED chip 56 of FIGS. 6A to 6C for embodiments where the n-contact interconnects 40-2 along the perimeter of the active LED structure 12 are formed with a different shape. According to principles of the present disclosure, the shapes of the n-contact interconnects 40-2 may be adjusted to tailor current injection patterns. For example, the n-contact interconnects 40-2 of FIG. 7A have smaller overall shapes than the n-contact interconnects 40-2 of FIG. 6A to adjust current injection. Moreover, the n-contact interconnects 40-2 of FIG. 7A have rounded or half circle shapes to adjust current injection profiles compared with the larger n-contact interconnects 40-2 of FIG. 6A with elongated linear edges.

Depending on the embodiment and the targeted current injection profile, the n-contact interconnects 40-2 along the perimeter of the active LED structure 12 may have various shapes. FIGS. 7B to 7G illustrate top views of various exemplary shapes that may be implemented for the n-contact interconnects 40-2. In FIG. 7B, the n-contact interconnect 40-2 forms a circular shape for radial current injection. In FIG. 7C, the n-contact interconnect 40-2 forms a triangular shape. In certain embodiments a corner of the triangular shape may point toward the active LED structure for more targeted current injection. In FIG. 7D, the n-contact interconnect 40-2 forms a squared shape with beveled corners that may point toward the active LED structure to more evenly distribute current injection. In FIG. 7E, the n-contact interconnect 40-2 forms a hexagonal shape with increased edges for current injection. In FIG. 7F, the n-contact interconnect 40-2 forms a cross shape that may extend relative to the active LED structure 12 of FIG. 7A to direct current from multiple sides of the cross shape. Additionally, connecting edges of the cross shape may be curved for more even current injection in these areas. In FIG. 7G, the n-contact interconnect 40-2 forms a trapezoid shape where a small side of the trapezoid may be pointed toward the active LED structure 12 of FIG. 7A or away from it depending on the desired current injection profile.

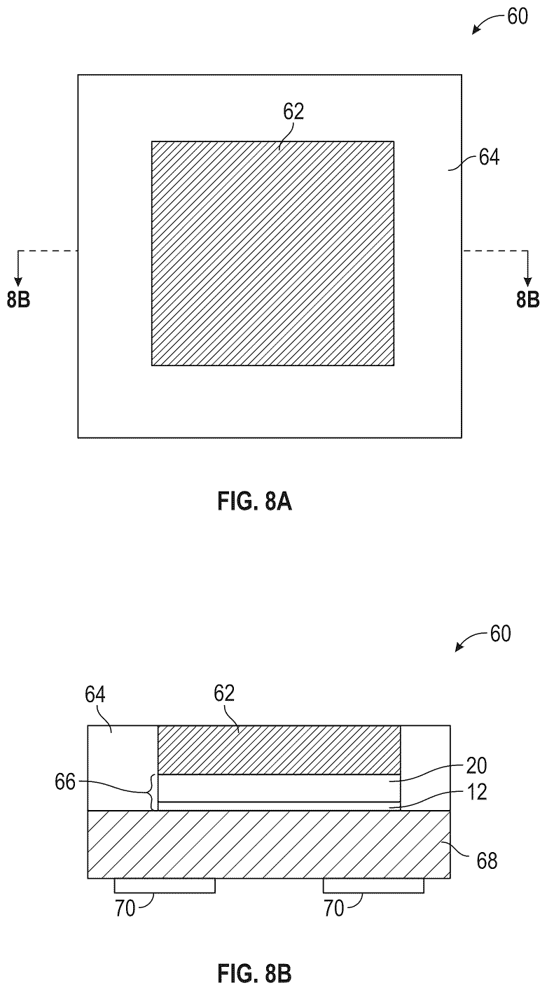

FIG. 8A is a top view of an LED package 60 according to principles of the present disclosure. FIG. 8B is a cross-sectional view of the LED package 60 of FIG. 8A taken along the cross-sectional line 8B-8B of FIG. 8A. The LED package 60 includes a wavelength conversion element 62, a light-altering material 64, an LED chip 66, and a submount 68. The LED package 60 may embody a surface mount LED component structured to be mounted and electrically coupled to another surface by way of package contact pads 70. The package contact pads 70 form anode and cathode contact pads on a bottom surface of the submount 68 and are electrically coupled to the LED chip 66 by way of electrically conductive paths such as vias that extend through the submount 68.

The LED chip 66 may be the same as the LED chip 10 of FIGS. 1 to 5E, the LED chip 56 of FIGS. 6A to 6C, or the LED chip 58 of FIG. 7A. In this manner, the LED chip 66 may include arrangements of the dielectric reflective layer 22 with the etch stop layer 44 and/or arrangements of n-contact interconnects 40 and corresponding reflective layer interconnects 26 as described above for FIGS. 1 to 7G. As illustrated, the LED chip 66 embodies a flip-chip structure where the active LED structure 12 is positioned between the substrate 20 and the submount 68. Accordingly, light generated by the active LED structure 12 that is reflected and/or redirected by the dielectric reflective layer 22 as described above with respect to FIGS. 1 to 4 may pass through the substrate 20 before exiting the LED chip 66. As described above, the substrate 20 may embody a light-transparent substrate such as sapphire. Despite being light-transparent to wavelengths generated by the active LED structure 12, an overall thickness of the substrate 20 may be reduced to promote increased light extraction. For example, the substrate 20 may be thinned to have a thickness in a range from 50 μm to 100 μm, or in a range from 60 μm to 90 μm, or in a range from 60 μm to 80 μm. Such thickness ranges for the substrate 20 are equally applicable to the LED chip 10 of FIGS. 1 to 5E, the LED chip 56 of FIGS. 6A to 6C, and the LED chip 58 of FIG. 7A. By reducing the thickness of the substrate 20, increased amounts of light may exit the LED chip 66 in a desired direction away from the submount 68.

Moreover, various structures present in the LED package 60 may further enhance light extraction and efficiency for the LED package 60 in combination with the above-described improvements for the LED chip 66. For example, the presence of the light-altering material 64 provides a light-reflective material, such as a white material, that laterally surrounds peripheral edges of the LED chip 66. Accordingly, laterally propagating light through the LED chip 66 and/or the substrate 20 may be redirected by the light-altering material 64 to travel through the wavelength conversion element 62. In certain embodiments, the wavelength conversion element 62 may comprise a coating of lumiphoric material such as phosphor on a transparent support element, a phosphor-in-glass structure, a ceramic phosphor plate, or a single crystal phosphor structure.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) chip comprising:
an active LED structure comprising an n-type layer, a p-type layer, and an active layer between the n-type layer and the p-type layer;
a dielectric reflective layer on the active LED structure, the dielectric reflective layer comprising at least one dielectric layer and an etch stop layer between the at least one dielectric layer and the active LED structure; and
a current spreading layer between the etch stop layer and the active LED structure.

2. The LED chip of claim 1, wherein the active LED structure defines at least one mesa bounded by a mesa sidewall, and wherein the current spreading is inset from the mesa sidewall such that a portion of the dielectric reflective layer contacts the active LED structure adjacent the current spreading layer.

3. The LED chip of claim 1, wherein the at least one dielectric layer comprises an alternating layer structure formed by a plurality of first dielectric layers in an alternating arrangement with a plurality of second dielectric layers.

4. The LED chip of claim 3, wherein the plurality of first dielectric layers and the plurality of second dielectric layers collectively form an aperiodic Bragg reflector.

5. The LED chip of claim 4, wherein a thickest layer of the alternating layer structure is positioned closer to the active LED structure than any other layer of the alternating layer structure, and the thickest layer of the alternating layer structure is at least ten times thicker than the thinnest layer of the alternating layer structure.

6. The LED chip of claim 1, wherein the etch stop layer comprises an atomic layer deposition layer.

7. The LED chip of claim 6, wherein the atomic layer deposition layer comprises aluminum oxide.

8. The LED chip of claim 6, wherein the etch stop layer comprises a thickness in a range from 25 nm to 200 nm.

9. The LED chip of claim 1, further comprising an adhesion layer on the dielectric reflective layer such that the at least one dielectric layer is between the adhesion layer and the etch stop layer, wherein the etch stop layer comprises a greater thickness than the adhesion layer.

10. The LED chip of claim 9, wherein the etch stop layer comprises a lower porosity than the adhesion layer.

11. The LED chip of claim 1, further comprising an opening extending through the dielectric reflective layer;
wherein a surface of the at least one dielectric layer at the opening forms a first angle relative to the active LED structure in a range from 15 degrees to 35 degrees; and
wherein a surface of the etch stop layer at the opening forms a second angle relative to the active LED structure in a range from 70 degrees to 90 degrees.

12. The LED chip of claim 1, further comprising a substrate on the active LED structure, wherein the active LED structure is between the dielectric reflective layer and the substrate, and the substrate comprises a thickness in a range from 50 μm to 100 μm.

13. A method for forming a light-emitting diode (LED) chip, the method comprising:
forming an active LED structure comprising an n-type layer, a p-type layer, and an active layer between the n-type layer and the p-type layer;
forming a dielectric reflective layer on the active LED structure, the dielectric reflective layer comprising an etch stop layer and at least one dielectric layer on the etch stop layer;
etching a first opening through the at least one dielectric layer to the etch stop layer; and
removing portions of the etch stop layer within the first opening.

14. The method of claim 13, further comprising forming a current spreading layer on the active layer before forming the dielectric reflective layer.

15. The method of claim 14, further comprising etching a second opening through the at least one dielectric layer to the etch stop layer, and removing portions of the etch stop layer within the second opening, wherein the first opening extends to the n-type layer and the second opening extends to the current spreading layer.

16. The method of claim 15, further comprising forming an n-contact interconnect within the first opening and a reflective layer interconnect within the second opening.

17. The method of claim 13, wherein a surface of the at least one dielectric layer at the first opening forms a first angle relative to the active LED structure in a range from 15 degrees to 35 degrees, and a surface of the etch stop layer at the first opening forms a second angle relative to the active LED structure in a range from 70 degrees to 90 degrees.

18. A light-emitting diode (LED) chip comprising:
an active LED structure comprising an n-type layer, a p-type layer, and an active layer between the n-type layer and the p-type layer, the active LED structure forming a mesa bounded by a mesa sidewall;
a dielectric reflective layer on the active LED structure;
a first n-contact interconnect extending through the dielectric reflective layer from a top surface of the mesa, the first n-contact interconnect being electrically coupled with the n-type layer;
a second n-contact interconnect extending through the dielectric reflective layer outside a perimeter edge of the active LED structure defined by the mesa sidewall, the second n-contact interconnect being electrically coupled with the n-type layer;
a first reflective layer interconnect extending through the dielectric reflective layer from the top surface of the mesa, the first reflective layer interconnect being electrically coupled with the p-type layer; and
a second reflective layer interconnect extending through the dielectric reflective layer from the top surface of the mesa, the second reflective layer interconnect being electrically coupled with the p-type layer, wherein the second reflective layer interconnect is closer to the second n-contact interconnect than the first reflective layer interconnect, and the second reflective layer interconnect is larger than the first reflective layer interconnect.

19. The LED chip of claim 18, wherein the second reflective layer interconnect forms an elongated shape that is longer than a lateral width of the second n-contact interconnect.

20. The LED chip of claim 19, wherein a middle portion of the second reflective layer interconnect extends parallel to the second n-contact interconnect, and end portions of the of the second reflective layer interconnect extend in an angled manner relative to the middle portion and toward the mesa sidewall.

21. The LED chip of claim 18, further comprising a third reflective layer interconnect extending through the dielectric reflective layer from the top surface of the mesa, the third reflective layer interconnect being electrically coupled with the p-type layer, wherein the third reflective layer interconnect forms a ring shape on the active LED structure and the first n-contact interconnect is aligned at a center of the ring shape.

22. The LED chip of claim 18, wherein the dielectric reflective layer comprises a plurality of dielectric layers and an etch stop layer between the plurality of dielectric layers and the active LED structure.

23. The LED chip of claim 22, wherein the plurality of dielectric layers comprises an aperiodic Bragg reflector.

24. The LED chip of claim 22, further comprising a current spreading layer between the etch stop layer and the active LED structure, wherein the current spreading layer is inset from the mesa sidewall such that a portion of the dielectric reflective layer contacts the active LED structure adjacent the current spreading layer.

25. The LED chip of claim 18, further comprising a substrate on the active LED structure, wherein the active LED structure is between the dielectric reflective layer and the substrate, and the substrate comprises a thickness in a range from 50 μm to 100 μm.
